(19) United States
(12) Patent Application Publication
(10) Pub. No.: US 2026/0173425 A1
(43) Pub. Date: Jun. 18, 2026

(54) SEMICONDUCTOR DEVICE AND MANUFACTURING METHOD THEREOF

(71) Applicant: Powerchip Semiconductor Manufacturing Corporation, Hsinchu (TW)

(72) Inventors: Ling Yen Yeh, Hsinchu (TW); Shih-Ci Yen, Hsinchu County (TW); Hiroshi Yoshida, Hsinchu City (TW)

(73) Assignee: Powerchip Semiconductor Manufacturing Corporation, Hsinchu (TW)

(21) Appl. No.: 18/985,059

(22) Filed: Dec. 18, 2024

(51) Int. Cl. H10D 30/01; H01L 21/02; H01L 21/311; H01L 21/3213; H10D 30/60; H10D 62/80; H10D 64/23; H10D 64/27

(52) U.S. Cl. CPC H10D 30/0273; H10D 30/60; H10D 62/875; H10D 64/258; H10D 64/514; H10P 50/267; H10P 50/283; H10P 70/23

(57) ABSTRACT

A semiconductor device includes a substrate, a dielectric layer over the substrate, an oxide semiconductor layer disposed on the dielectric layer, a gate electrode, a gate insulating layer, a protection layer, and a plurality of source/drain electrode layers. The gate insulating layer is formed over a surface of the oxide semiconductor layer. The gate electrode is formed over a surface of the gate insulating layer. The protection layer is formed extending from an edge of the gate insulating layer along the surface of the oxide semiconductor layer. The source/drain electrode layers are disposed on the oxide semiconductor layer and the protection layer at two sides of the gate electrode.

### BACKGROUND

### Technical Field

The disclosure relates to a semiconductor manufacture technique, and particularly relates to a semiconductor device and a manufacturing method thereof.

### Description of Related Art

An oxide semiconductor field effect transistor (OSFET) is provided in a BEOL (back end of line) structure for advanced applications such as oxide semiconductor (OS)/silicon (Si) driver for an organic light-emitting diode (OLED) display.

However, during etching the source/drain electrode layer of OSFET, metal residue is easily remained on the oxide semiconductor layer of OSFET, and it may affect the electrical property of the device, such as source/drain short. Moreover, the method for etching the source/drain electrode layer is usually a plasma etching, and thus a surface of the oxide semiconductor layer may be damaged by the plasma etching resulting in degradation of characteristics and reliability in OSFET device.

### SUMMARY

The disclosure provides a semiconductor device and a manufacturing method thereof to prevent from etching residue and plasma damage to the surface of the oxide semiconductor layer.

The semiconductor device of one embodiment of the disclosure includes a substrate, a dielectric layer, an oxide semiconductor layer, a gate electrode, a gate insulating layer, a protection layer, and a plurality of source/drain electrode layers. The dielectric layer is disposed over the substrate. The oxide semiconductor layer is disposed on the dielectric layer. The gate insulating layer is formed over a surface of the oxide semiconductor layer. The gate electrode is formed over a surface of the gate insulating layer. The protection layer is formed extending from an edge of the gate insulating layer along the surface of the oxide semiconductor layer. The source/drain electrode layers are disposed on the oxide semiconductor layer and the protection layer at two sides of the gate electrode.

In one embodiment of the disclosure, the protection layer has an extending direction the same as an extending direction of the gate electrode in a top view.

In one embodiment of the disclosure, the protection layer has an extending direction vertical to an extending direction of the oxide semiconductor layer in a top view.

In one embodiment of the disclosure, a first portion of the oxide semiconductor layer is covered by the protection layer, and a second portion of the oxide semiconductor layer is covered by the source/drain electrode layers.

In one embodiment of the disclosure, the semiconductor device further comprises an interlayer dielectric layer formed on the source/drain electrode layers and the substrate.

In one embodiment of the disclosure, the gate insulating layer is further disposed on sidewalls of the gate electrode.

In one embodiment of the disclosure, the gate electrode protrudes from the plurality of source/drain electrode layers in a cross-sectional view.

In one embodiment of the disclosure, the plurality of source/drain electrode layers is further disposed on sidewalls of the oxide semiconductor layer.

The manufacturing method of a semiconductor device of another embodiment of the disclosure includes forming a dielectric layer over a substrate, forming an oxide semiconductor layer on the dielectric layer, forming a protection layer on a portion of the oxide semiconductor layer, forming a metal layer on the oxide semiconductor layer and the protection layer, forming an interlayer dielectric layer on the metal layer, forming a trench in the interlayer dielectric layer, the metal layer and a top of the protection layer by a plasma etching, removing residue of the protection layer under the trench by a wet etching until a surface of the oxide semiconductor layer is exposed, forming a gate insulating layer on the surface of the oxide semiconductor layer, and forming a gate electrode on the gate insulating layer.

In another embodiment of the disclosure, a step of forming the gate insulating layer comprises conformally depositing an oxide layer on sidewalls of the trench and the surface of the oxide semiconductor layer.

In another embodiment of the disclosure, after forming the metal layer, the metal layer is patterned to define a border of a plurality of source/drain electrode layers.

In another embodiment of the disclosure, the border of the source/drain electrode layers is defined beyond the oxide semiconductor layer.

In another embodiment of the disclosure, the plasma etching is performed in a time mode.

In another embodiment of the disclosure, a material of the protection layer comprises silicon oxide, and an etchant of the wet etching comprises hydrofluoric acid (HF).

In another embodiment of the disclosure, a material of the protection layer comprises silicon nitride, and an etchant of the wet etching comprises phosphoric acid (H₃PO₄).

In another embodiment of the disclosure, steps of forming the gate electrode includes forming a conductive material on the substrate to fill up the trench, and then removing the conductive material outside the trench.

Based on the above, since the protection layer is formed on the surface of the oxide semiconductor layer before etching the source/drain electrode layer, the surface of the oxide semiconductor layer may be protected from etching residues and plasma damage. Therefore, source/drain short may be avoided, and the degradations of the device performance and the reliability are also eliminated.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 a schematic top view of a semiconductor device according to a first embodiment of the disclosure.

FIG. 2 is a cross-sectional view along line II-II′ of FIG. 1.

FIG. 3 is a cross-sectional view along line III-III′ of FIG. 1.

FIG. 4A to FIG. 4F are schematic cross-sectional views of a manufacturing process of a semiconductor device according to a second embodiment of the disclosure.

### DESCRIPTION OF THE EMBODIMENTS

Referring to the embodiments below and the accompanied drawings for a sufficient understanding of the disclosure. These embodiments are described in sufficient detail to enable those skilled in the art to practice the disclosure. However, the disclosure may be implemented in many other different forms and should not be limited to the embodiments described hereinafter. Other embodiments may be utilized and structural, logical, and electrical changes may be made without departing from the scope of the present disclosure. In the drawings, for clarity, the elements and relative dimensions thereof may not be scaled. For easy understanding, the same elements in the following embodiments will be denoted by the same reference numerals.

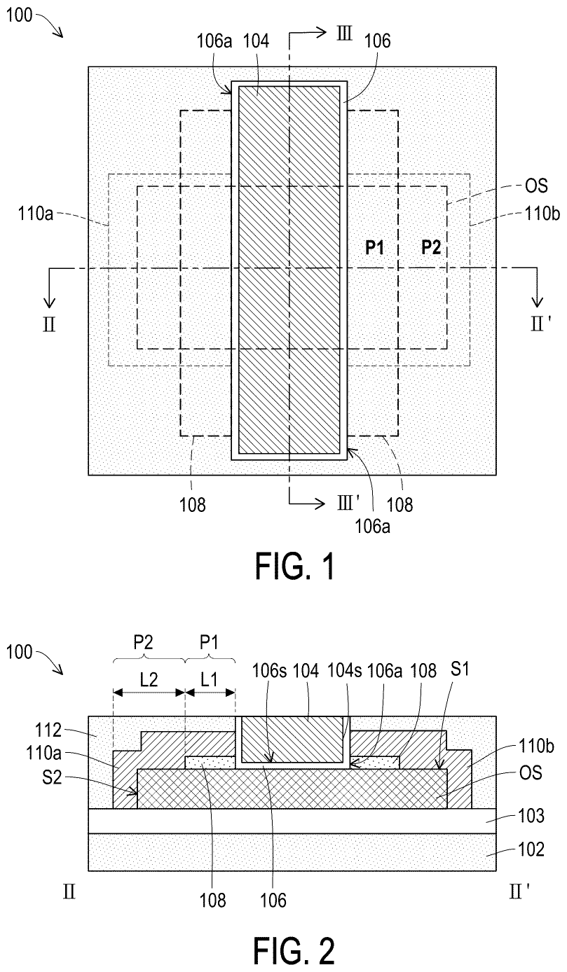

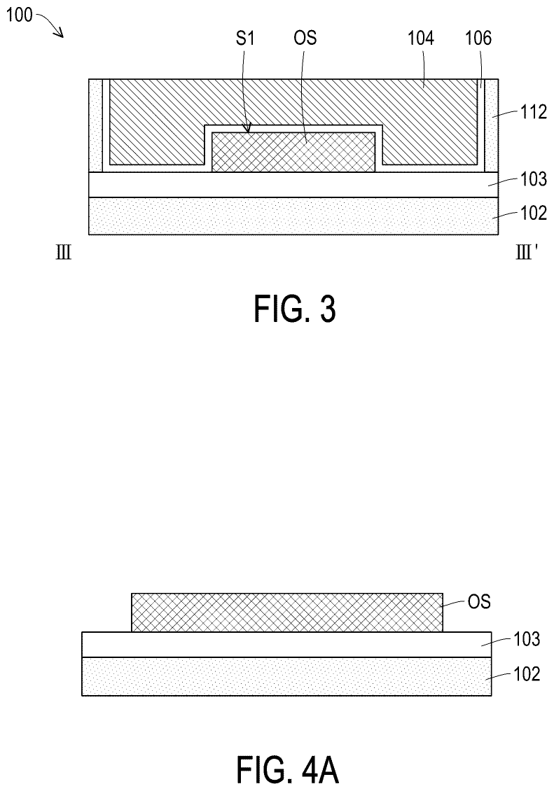

FIG. 1 a schematic top view of a semiconductor device according to a first embodiment of the disclosure. FIG. 2 is a cross-sectional view along line II-II′ of FIG. 1. FIG. 3 is a cross-sectional view along line III-III′ of FIG. 1.

Referring to FIG. 1, FIG. 2 and FIG. 3, a semiconductor device 100 of the first embodiment includes at least a substrate 102, a dielectric layer 103, an oxide semiconductor layer OS, a gate electrode 104, a gate insulating layer 106, a protection layer 108, and a plurality of source/drain electrode layers 110a and 110b. The dielectric layer 103 is disposed over the substrate 102. In some embodiments, the dielectric layer 103 may be one layer of a BEOL (back end of line) structure (not shown), but it is not limited thereto. The oxide semiconductor layer OS is disposed on the dielectric layer 103, wherein a material of the oxide semiconductor layer OS includes, for instance, gallium oxide (GaOₓ), gallium zinc oxide (Ga₂ZnₓO_{y}) or indium gallium zinc oxide (IGZO). The gate insulating layer 106 is formed over a surface S1 of the oxide semiconductor layer OS. The gate electrode 104 is formed over a surface 106s of the gate insulating layer 106, wherein a material of the gate electrode 104 may be metal materials such as Cu, Al, Mo, Cr, Ti, TiN, W and/or Ta. In some embodiments, the gate insulating layer 106 is further disposed on sidewalls 104s of the gate electrode 104. In some embodiments, a material of gate insulating layer 106 includes silicon oxide, silicon nitride, silicon oxynitride, aluminum oxide, gallium oxide or gallium zinc oxide. The protection layer 108 is formed extending from an edge 106a of the gate insulating layer 106 along the surface S1 of the oxide semiconductor layer OS, wherein a material of the protection layer 108 includes, for instance, silicon oxide, silicon nitride, or the like.

In some embodiments, the protection layer 108 has an extending direction the same as an extending direction of the gate electrode 104 in a top view. The extending direction of the protection layer 108 is parallel to the line III-III′ of FIG. 1. In some embodiments, the protection layer 108 has an extending direction vertical to an extending direction of the oxide semiconductor layer OS in a top view, wherein the extending direction of the oxide semiconductor layer OS is parallel to the line II-II′ of FIG. 1.

The source/drain electrode layers 110a and 110b are disposed on the oxide semiconductor layer OS and the protection layer 108 at two sides of the gate electrode 104. A material of the source/drain electrode layers 110a and 110b may be metal materials such as Cu, Al, Mo, Cr, Ti, TiN, and/or Ta. In some embodiments, a first portion P1 of the oxide semiconductor layer OS is covered by the protection layer 108, and a second portion P2 of the oxide semiconductor layer OS is covered by the source/drain electrode layers 110a and 110b. In some embodiments, a length L1 of the first portion P1 may be a range of 0.1 um to 0.2 um for good electrical characterization, and a length L2 of the second portion P2 may be larger than 0.2 um to form via on the metal material. In some embodiments, the gate electrode 104 protrudes from the source/drain electrode layers 110a and 110b in FIG. 2. In some embodiments, the semiconductor device 100 may further comprise an interlayer dielectric layer 112 formed on the source/drain electrode layers 110a and 110b and the dielectric layer 103, and the top surface of the interlayer dielectric layer 112 may be coplanar with the top surface of gate electrode 104.

In some embodiments, the source/drain electrode layers 110a and 110b are further disposed on sidewalls S2 of the oxide semiconductor layer OS. Accordingly, the source/drain electrode layers 110a and 110b are in direct contact with the first oxide semiconductor layer 204 and the protection layer 108. Furthermore, the source/drain electrode layers 110a and 110b may be symmetrical with respect to the gate electrode 104, but it is not limited thereto. The gate electrode 104, the gate insulating layer 106, the source/drain electrode layers 110a and 110b, the protection layer 108, and the oxide semiconductor layer OS constitute an oxide semiconductor field effect transistor.

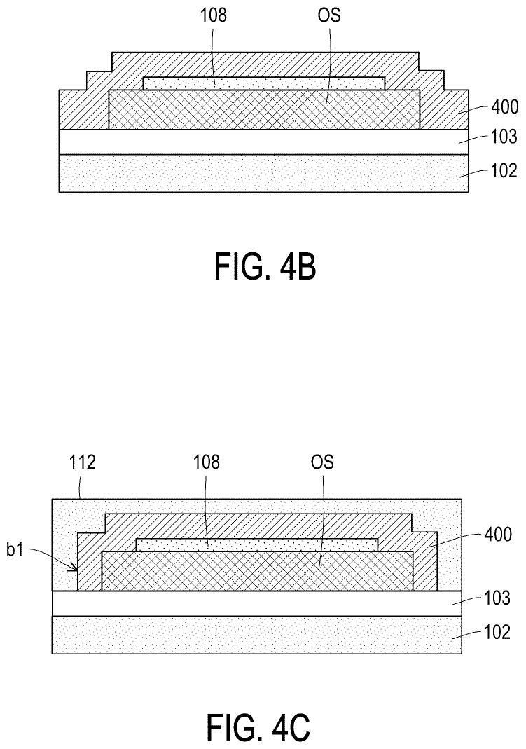

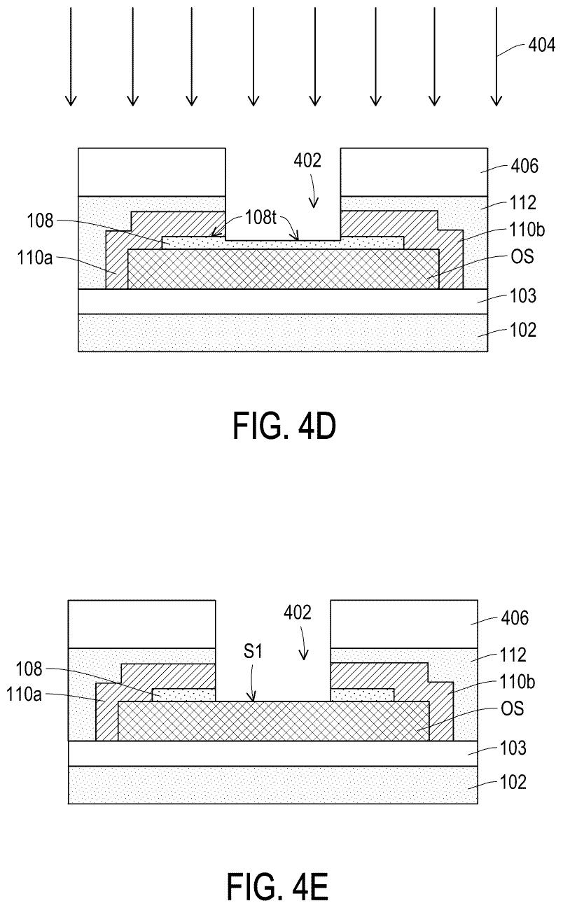

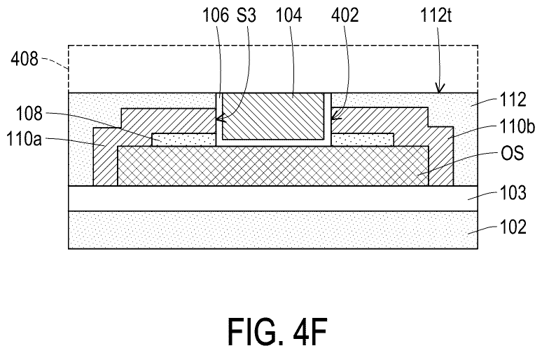

FIG. 4A to FIG. 4F are schematic cross-sectional views of a manufacturing process of a semiconductor device according to a second embodiment of the disclosure, wherein the same reference numerals as those in the first embodiment are used to indicate the same or similar components, and the content of the same or similar components is also as provided in the content in the first embodiment and is not repeated herein.

Referring to FIG. 4A, a dielectric layer 103 is formed over a substrate 102, and an oxide semiconductor layer OS is formed on the dielectric layer 103. In some embodiments, the step of forming the oxide semiconductor layer OS comprises depositing an oxide semiconductor material (not shown) on the dielectric layer 103 and then patterning the oxide semiconductor material.

Thereafter, referring to FIG. 4B, a protection layer 108 is formed on a portion of the oxide semiconductor layer OS. In some embodiments, the step of forming the protection layer 108 comprises depositing a protection material (not shown) on the oxide semiconductor layer OS and the dielectric layer 103 and then patterning the protection material until the portion of the oxide semiconductor layer OS is exposed. Next, a metal layer 400 is formed on the oxide semiconductor layer OS and the protection layer 108.

Then, referring to FIG. 4C, the metal layer 400 may be patterned to define a border b1 of a subsequently-formed source/drain electrode layer. In some embodiments, the border b1 is defined beyond the oxide semiconductor layer OS. In some embodiment, an interlayer dielectric layer 112 may be formed on the metal layer 400 and the dielectric layer 103, wherein the method of forming the interlayer dielectric layer 112 comprises CVD, spin-on coating, or the like.

Next, referring to FIG. 4D, a trench 402 is formed in the interlayer dielectric layer 112, the metal layer 400 of FIG. 4C and a top 108t of the protection layer 108 by a plasma etching 404, thereby forming a source/drain electrode layer 110a and a source/drain electrode layer 110b respectively. In some embodiment, a patterned mask 406 is formed on the interlayer dielectric layer 112 as an etching mask during the plasma etching 404, wherein the patterned mask 406 may be a patterned photoresist. In some embodiments, the plasma etching 404 is performed in a time mode.

Thereafter, referring to FIG. 4E, a wet etching is performed to remove residue of the protection layer 108 under the trench 402 until a surface S1 of the oxide semiconductor layer OS is exposed. In some embodiments, the material of the protection layer 108 comprises silicon oxide, and the etchant of the wet etching may include hydrofluoric acid (HF). In some embodiments, the material of the protection layer 108 comprises silicon nitride, and the etchant of the wet etching may include phosphoric acid (H₃PO₄). In some embodiments, the patterned mask 406 may be utilized as an etching mask during the wet etching.

Then, referring to FIG. 4F, after removing the patterned mask 406 of FIG. 4E, a gate insulating layer 106 is formed on the surface S1 of the oxide semiconductor layer OS, and then a gate electrode 104 is formed on the gate insulating layer 106. In some embodiments, the step of forming the gate insulating layer 106 comprises conformally depositing an oxide layer on sidewalls S3 of the trench 402 and the surface S1 of the oxide semiconductor layer OS. In some embodiments, the steps of forming the gate electrode 104 includes forming a conductive material 408 over the substrate 102 to fill up the trench 402, and then the conductive material 408 outside the trench 402 is removed. In some embodiments, the step of removing the conductive material 408 may include perform a planarization process such as a CMP (chemical mechanical polishing) process on the conductive material 408 until the top 112t of the interlayer dielectric layer 112 is exposed.

In summary, the semiconductor device according to the disclosure has a protection layer on the surface of the oxide semiconductor layer, and it can protect the surface of the oxide semiconductor layer during plasma etching source/drain electrodes. Accordingly, etching residues on the oxide semiconductor layer and plasma damage to the oxide semiconductor layer may be prevented. Therefore, source/drain short may be avoided, and the degradations of the device performance and the reliability are also eliminated.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a substrate;
a dielectric layer disposed over the substrate;
an oxide semiconductor layer disposed on the dielectric layer;
a gate insulating layer formed over a surface of the oxide semiconductor layer;
a gate electrode formed over a surface of the gate insulating layer;
a protection layer formed extending from an edge of the gate insulating layer along the surface of the oxide semiconductor layer; and
a plurality of source/drain electrode layers disposed on the oxide semiconductor layer and the protection layer at two sides of the gate electrode.

2. The semiconductor device of claim 1, wherein in a top view, the protection layer has an extending direction the same as an extending direction of the gate electrode.

3. The semiconductor device of claim 1, wherein in a top view, the protection layer has an extending direction vertical to an extending direction of the oxide semiconductor layer.

4. The semiconductor device of claim 1, wherein a first portion of the oxide semiconductor layer is covered by the protection layer, and a second portion of the oxide semiconductor layer is covered by the plurality of source/drain electrode layers.

5. The semiconductor device of claim 1, further comprising an interlayer dielectric layer, formed on the plurality of source/drain electrode layers and the substrate.

6. The semiconductor device of claim 1, wherein the gate insulating layer is further disposed on sidewalls of the gate electrode.

7. The semiconductor device of claim 1, wherein in a cross-sectional view, the gate electrode protrudes from the plurality of source/drain electrode layers.

8. The semiconductor device of claim 1, wherein the plurality of source/drain electrode layers is further disposed on sidewalls of the oxide semiconductor layer.

9. A manufacturing method of a semiconductor device, comprising:
forming a dielectric layer over a substrate;
forming an oxide semiconductor layer over the dielectric layer;
forming a protection layer on a portion of the oxide semiconductor layer;
forming a metal layer on the oxide semiconductor layer and the protection layer;
forming an interlayer dielectric layer on the metal layer;
forming a trench in the interlayer dielectric layer, the metal layer and a top of the protection layer by a plasma etching;
removing residue of the protection layer under the trench by a wet etching until a surface of the oxide semiconductor layer is exposed;
forming a gate insulating layer on the surface of the oxide semiconductor layer; and
forming a gate electrode on the gate insulating layer.

10. The manufacturing method of claim 9, wherein a step of forming the gate insulating layer comprises conformally depositing an oxide layer on sidewalls of the trench and the surface of the oxide semiconductor layer.

11. The manufacturing method of claim 9, wherein after forming the metal layer, further comprising patterning the metal layer to define a border of a plurality of source/drain electrode layers.

12. The manufacturing method of claim 11, wherein the border of the plurality of source/drain electrode layers is defined beyond the oxide semiconductor layer.

13. The manufacturing method of claim 9, wherein the plasma etching is performed in a time mode.

14. The manufacturing method of claim 9, wherein a material of the protection layer comprises silicon oxide, and an etchant of the wet etching comprises hydrofluoric acid.

15. The manufacturing method of claim 9, wherein a material of the protection layer comprises silicon nitride, and an etchant of the wet etching comprises phosphoric acid.

16. The manufacturing method of claim 9, wherein steps of forming the gate electrode comprises:
forming a conductive material on the substrate to fill up the trench; and
removing the conductive material outside the trench.
